(19) United States
(12) Patent Application Publication
(10) Pub. No.: US 2008/0093733 A1
(43) Pub. Date: Apr. 24, 2008

(54) CHIP PACKAGE AND MANUFACTURING METHOD THEREOF

(75) Inventor: CHI-HSING HSU, TAIPEI HSIEN (TW)

Correspondence Address: J C PATENTS, INC., 4 VENTURE, SUITE 250, IRVINE, CA, 92618, US

(73) Assignee: VIA TECHNOLOGIES, INC., TAIPEI HSIEN (TW)

(21) Appl. No.: 11/565,866

(22) Filed: Dec. 1, 2006

(30) Foreign Application Priority Data
Oct. 23, 2006 (TW) 95138948

(51) Int. Cl. H01L 23/34

(52) U.S. Cl. 257/722; 257/712

(57) ABSTRACT

A chip package including a carrier, at least one chip, a heat spreader, and a thermal interface material (TIM) is provided. The chip is disposed on the carrier and is electrically connected to the carrier. The heat spreader is disposed on the carrier, wherein the heat spreader and the carrier together form a closed space. The chip is located in the closed space. The closed space is filled with the TIM. In addition, a method of manufacturing the chip package is also provided.

### CROSS-REFERENCE TO RELATED APPLICATION

This application claims the priority benefit of Taiwan application serial no. 95138948, filed Oct. 23, 2006. All disclosure of the Taiwan application is incorporated herein by reference.

### BACKGROUND OF THE INVENTION

1. Field of the Invention

The present invention relates to a semiconductor device and a manufacturing method thereof. More particularly, the present invention relates to a chip package and a manufacturing method thereof.

2. Description of Related Art

In the semiconductor industry, the production of integrated circuits (IC) may be mainly divided into three stages, IC design, IC process and IC package.

In the IC process, chips are formed by the steps of wafer manufacturing, IC forming, and wafer sawing etc. The wafer has an active surface, generally referring to the surface of the wafer having the active element. After the IC in the wafer is completed, a plurality of bonding pads is disposed on the active surface of the wafer, such that a chip formed after wafer sawing may be electrically connected to a carrier through the bonding pads. The carrier is, for example, a leadframe or a package substrate. The chip may be connected to the carrier through wire bonding technology or flip chip bonding technology, such that the bonding pads of the chip may be electrically connected to the contacts of the carrier to complete a chip package.

For the flip chip bonding technology, usually after the bonding pads are formed on the active surface of the wafer, a bump is formed on each bonding pad to electrically connect the chip to the external package substrate. Because the bumps are usually arranged on the active surface of the chip in a manner of array, the flip chip bonding technology is suitable for the chip package with high contact number and high contact density, for example the flip chip/ball grid array package widely applied in the semiconductor packaging industry. In addition, as compared to the wire bonding technology, because the bumps may provide a short transmitting path between the chip and the carrier, the flip chip bonding technology may improve the electrical performance of the chip package.

In the conventional flip chip bonding process, after the chip is electrically connected to and fixed on the substrate through a plurality of bumps, in order to enhance the heat spreading effect of the chip, usually a heat spreader with cavity is attached on the back of the chip by the thermal adhesive, such that the chip is located in the cavity of the heat spreader disposed on the substrate. During the operation of the conventional chip package, the heat generated by the chip is transferred to the external environment through the thermal adhesive and the heat spreader on the back of the chip, so the temperature at the part of the heat spreader thermally coupled to the back of the chip is higher, and the temperature of the other part of the heat spreader is lower. In other words, the heat spreading efficiency of the conventional heat spreader of the chip package is poor. However, with the design trend of the high energy consumption and the high frequency during the operating of the chip, the heat spreading efficiency of the heat spreader attached on the chip cannot meet the requirement, therefore it is necessary to improve the heat spreading efficiency of the conventional chip package.

### SUMMARY OF THE INVENTION

Accordingly, the present invention is directed to a chip package having an improved heat spreading efficiency.

The present invention is also directed to a method of manufacturing the chip package with the improved heat spreading efficiency for reducing the manufacturing cost of the chip package.

The present invention provides a chip package, which comprises a carrier, at least one chip, a heat spreader and a thermal interface material (TIM). The chip is disposed on the carrier and is electrically connected to the carrier. The heat spreader is disposed on the carrier, wherein the heat spreader and the carrier form a closed space, and the chip is located in the closed space. In addition, the closed space is filled with the TIM.

The present invention provides a chip package, which comprises a carrier, at least one chip, a heat spreader, and a TIM. The chip is disposed on the carrier and is electrically connected to the carrier. The heat spreader is disposed on the carrier, wherein the heat spreader and the carrier form a closed space, and the chip is located in the closed space. In addition, the TIM is located in the closed space, wherein the TIM is in contact with an inner surface of the heat spreader.

The present invention provides a method of manufacturing the chip package, which comprises the following steps. First, a carrier is provided. Next, at least one chip is disposed on the carrier. Next, the chip is electrically connected to the carrier. Next, a thermal ring is disposed on the carrier such that the thermal ring surrounds the chip. Next, a containing space surrounded by the thermal ring on the carrier is filled with the TIM such that the TIM encapsulates the chip. Next, a thermal plate is disposed on the thermal ring such that the thermal plate covers the chip and a closed space formed by the thermal plate, the thermal ring and the carrier is filled with the TIM.

In order to the make aforementioned and other objects, features and advantages of the present invention comprehensible, a preferred embodiment accompanied with figures are described in detail below.

### BRIEF DESCRIPTION OF THE DRAWINGS

FIG. 1A is a schematic sectional view of a chip package according to a first embodiment of the present invention.

FIG. 1B is a schematic sectional view of another chip package according to the first embodiment of the present invention.

FIGS. 2A to 2G are schematic views of the process flow of the method of manufacturing the chip package of FIG. 1A.

FIG. 3 is a schematic sectional view of a chip package according to a second embodiment of the present invention.

### DESCRIPTION OF EMBODIMENTS

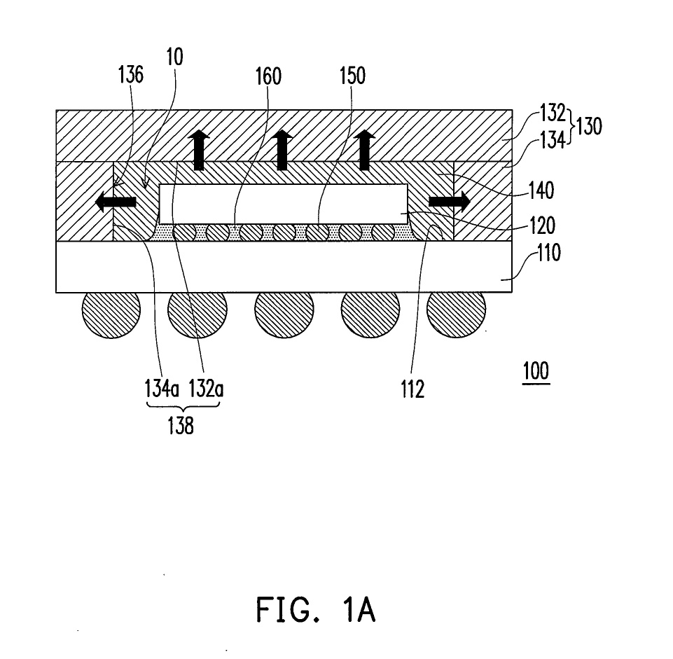

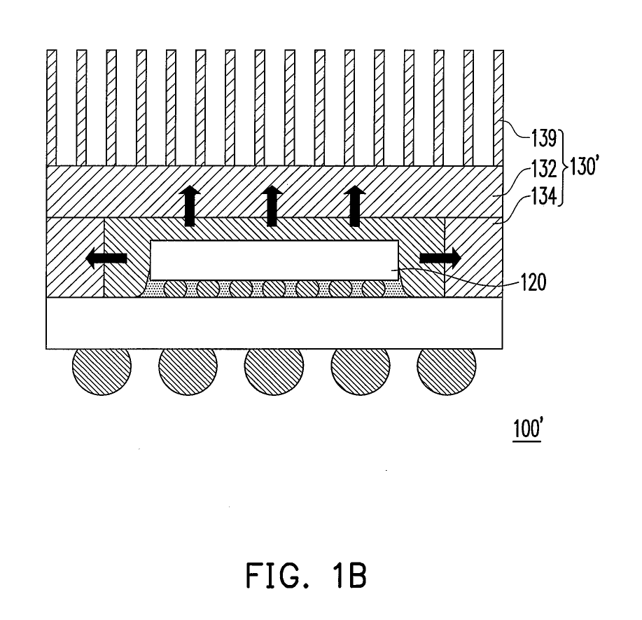

Referring to FIG. 1A, a schematic sectional view of a chip package according to the first embodiment of the present invention is shown. The chip package 100 of the first embodiment includes a carrier 110, at least one chip 120, a heat spreader 130 and a thermal interface material (TIM) 140. The chip 120 is disposed on the carrier 110 and is electrically connected to the carrier 110. The heat spreader 130 is disposed on the carrier 110, wherein the heat spreader 130 and the carrier 110 form a closed space 10, and the chip 120 is located in the closed space 10. In addition, the closed space 10 is filled with the TIM 140.

It should be noted that during the operation of the chip package 100, because the closed space 10 is filled with the TIM 140, the heat generated by the chip 120 may be conducted to the heat spreader 130 through the TIM 140. It is known from the black arrows of FIG. 1 that the heat generated by the chip 120 of this embodiment may be conducted to the heat spreader 130 from the back of the chip 120 and also from the side of the chip 120. Therefore, compared to the conventional art, the temperature of the heat spreader 130 of this embodiment is substantially uniform. In other words, the chip package 100 of this embodiment has better heat spreading efficiency.

The TIM 140 may be a thermally conductive compound or a thermally conductive elastomer. Particularly, the TIM 140 may be solder paste, thermal grease, or epoxy region with silicon dioxide or silver added. The TIM 140 may include metal materials such as tin or lead. It should be noted that the TIM 140 may be changed according to the requirement of the designer, and the first embodiment is used as an example but not to limit the present invention.

Particularly, the heat spreader 130 of the first embodiment includes a thermal plate 132 and a thermal ring 134. The thermal ring 134 is disposed on the thermal plate 132. The thermal ring 134 and the thermal plate 132 together form a cavity 136. And the thermal ring 134 is located between the thermal plate 132 and the carrier 110. Refer to FIG. 1 of in the first embodiment. The closed space 10 may be formed by the thermal plate 132, the thermal ring 134 and the carrier 110. And the TIM 140 filling out the closed space 10 is in contact with an inner surface 138 of the heat spreader 130. In other words, the TIM 140 of the first embodiment is in contact with the inner wall of the cavity 136 of the heat spreader 130.

It should be noted that the thermal plate 132 and the thermal ring 134 of the first embodiment may be respectively formed in advance and then combined by processing (see detailed illustrate hereafter). But the thermal plate 132 and the thermal ring 134 may be integrally formed according to the design requirement. In addition, referring to FIG. 1B, a schematic sectional view of another chip package according to the first embodiment of the present invention is shown. The heat spreader 130′ of the chip package 100′ further includes a plurality of fins 139 disposed on one side of the thermal plate 132 opposite to the thermal ring 134. In other words, the fins 139 extend from the thermal plate 132 towards the direction away from the chip 120. The function of the fins 139 is to increase the heat exchanging surface area between the heat spreader 130′ and the external environment, so as to improve the heat spreading efficiency of the heat spreader 130′.

Referring to FIG. 1A, the chip package 100 of the first embodiment further includes a plurality of conductive bumps 150 and an underfill layer 160, and the carrier 110 may be a circuit board. The conductive bumps 150 are disposed between the chip 120 and the carrier 110, and the underfill layer 160 encapsulates the conductive bumps 150. The underfill layer 160 is used to protect the conductive bumps 150. When the chip package 100 generates heat during operation, the underfill layer 160 may buffer the mismatch of the thermal strain generated between the heated carrier 110 and the heated chip 120.

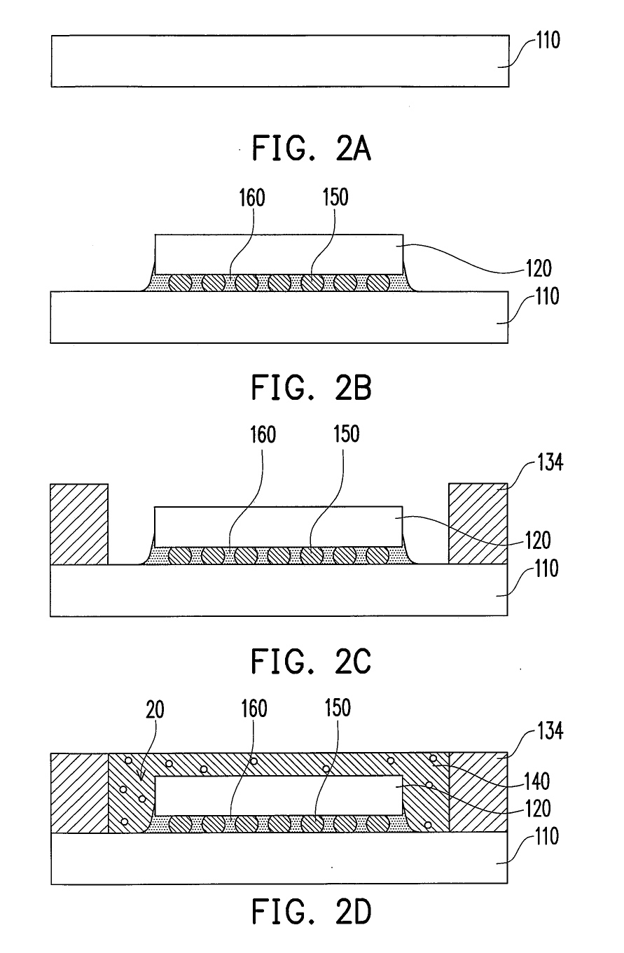

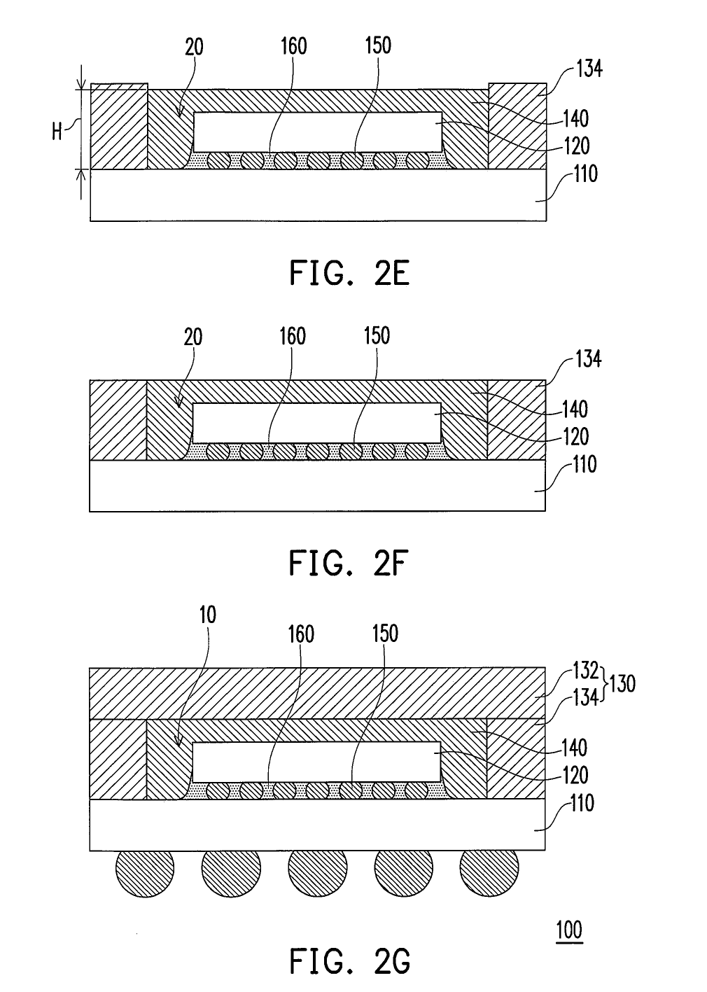

The method of manufacturing the chip package 100 of the first embodiment is illustrated in detail below. FIGS. 2A to 2G are schematic views of the process flow of the method of manufacturing the chip package of FIG. 1A. The method of manufacturing the chip package 100 of the first embodiment includes the following steps. First, referring to FIG. 2A, a carrier 110 is provided. Next, referring to FIG. 2B, at least one chip 120 is disposed on the carrier 110. Next, the chip 120 is electrically connected to the carrier 110.

In the first embodiment, the steps of disposing the chip 120 on the carrier 110 and electrically connecting the chip 120 to the carrier 110 are completed by the flip chip bonding technology, and the steps include the, following sub-steps. First, a plurality of conductive bumps 150 is formed on the chip 110 by, for example, an electroplating process. Next, the chip 120 is disposed on the carrier 110, and the conductive bumps 150 are reflowed, such that the conductive bumps 150 are electrically connected between the chip 120 and the carrier 110. Finally, an underfill layer 160 is formed to encapsulate the conductive bumps 150. The underfill layer 160 is usually formed by curing an underfill filling between the chip 120 and the carrier 110.

Next, referring to FIG. 2C, a thermal ring 134 is disposed on the carrier 110 by, for example, adhering such that the thermal ring 134 surrounds the chip 120. Next, referring to FIG. 2D, a containing space 20 surrounded by the thermal ring 134 on the carrier 110 is filled with a TIM 140 such that the TIM 140 encaplulates the chip 120.

Next, referring to FIG. 2E, in the first embodiment, after the step of filling the containing space 20 with the TIM 140, gases in the TIM 140 may be removed. If the TIM 140 is solid, gases in the TIM 140 are removed by vacuum extraction. If the TIM 140 is liquid, gases in the TIM 140 are removed by vacuum extraction or heating or both of the two. It should be noted that after gases in the TIM 140 are removed, the height H of the TIM 140 is usually reduced.

Then, referring to FIG. 2F, the TIM 140 is put again to fill the containing space 20, so as to encapsulate the chip 120. Next, referring to FIG. 2Q a thermal plate 132 is disposed on the thermal ring 134 by, for example, adhering or soldering, such that the thermal plate 132 covers the chip 120, and the TIM. 140 fills a closed space 10 formed by the thermal plate 132, the thermal ring 134 and the carrier 110. The thermal plate 132 and the thermal ring 134 constitute the heat spreader 130 of this embodiment.

Referring to FIG. 1A, in the first embodiment, the closed space 10 is enclosed by an inner surface 132a of the thermal plate 132, an inner surface 134a of the thermal ring 134, and a carrying surface 112 of the carrier 110. The inner surface 138 of the heat spreader 130 is composed of the inner surface 132a of the thermal plate 132 and the inner surface 134a of the thermal ring 134. After the TIM 140 fills the closed space 10, the TIM 140 is in contact with the inner surface 138 and the carrying surface 112. That is, the TIM 140 covers the inner surface 132a of the thermal plate 132, the inner surface 134a of the thermal ring 134, and the carrying surface 112 of the carrier 110.

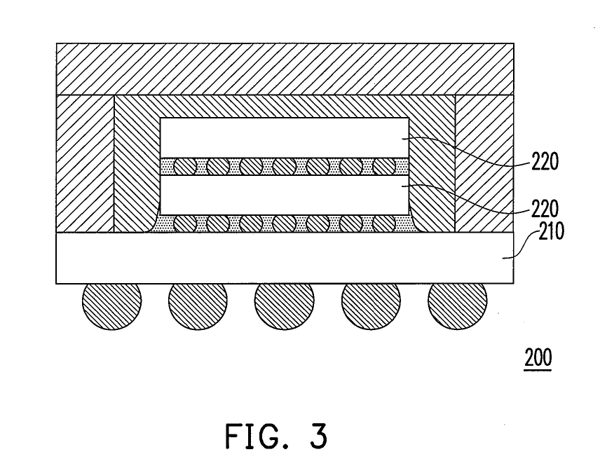

Referring to FIG. 3, a schematic sectional view of a chip package according to the second embodiment of the present invention is shown. The main difference of the chip package 200 of the second embodiment and the chip package 100 of the first embodiment is that the chip package 200 of the second embodiment includes a plurality of chips 220. The chips 220 are mutually electrically connected, and are disposed on the carrier 210 in the manner of stack. It should be noted that the quantity of the chips 220 and the method of disposing the chips 220 on the carrier 210 may be changed according to the requirement of the designer. This embodiment is only used as an example but not to limit the present invention.

To sum up, the chip package and the manufacturing method thereof according to the present invention has at least the following advantages.

1. During the operation of the chip package of the present invention, because the TIM fills the closed space, the heat generated by the chip may be effectively conducted to the heat spreader through the TIM. Therefore, the heat generated by the chip of the present invention may be transferred to the heat spreader from the back of the chip and also from the side of the chip. It is known from the above that as compared to the convention art, the temperature distribution in the heat spreader of the present invention is substantially uniform, that is, the heat spreading efficiency of the chip package of the present invention is better.

2. The steps of the method of manufacturing the chip package of the present invention may be integrated with the current process, so the manufacturing cost of the chip package with the improved heat spreading efficiency of the present invention is relatively low.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip package, comprising:
a carrier;
at least one chip disposed on the carrier and electrically connected to the carrier;
a heat spreader disposed on the carrier, wherein the heat spreader and the carrier together form a closed space, and the chip is located in the closed space; and
a thermal interface material (TIM) filling out the closed space.

2. The chip package as claimed in claim 1, wherein the heat spreader comprises:
a thermal plate; and
a thermal ring, disposed on the thermal plate, wherein the thermal ring and the thermal plate together form a cavity, and the thermal ring is located between the thermal plate and the carrier.

3. The chip package as claimed in claim 2, wherein the thermal plate and the thermal ring are integrally formed.

4. The chip package as claimed in claim 2, wherein the heat spreader further comprises a plurality of fins disposed on one side of the thermal plate opposite to the thermal ring.

5. The chip package as claimed in claim 1, wherein the TIM is solder paste, thermal grease, or epoxy resin with silicon dioxide or silver added.

6. The chip package as claimed in claim 1, further comprising:
a plurality of conductive bumps, disposed between the chip and the carrier; and
an underfill layer, encapsulating the conductive bumps.

7. The chip package as claimed in claim 1, wherein the carrier is a circuit board.

8. A chip package, comprising:
a carrier;
at least one chip, disposed on the carrier and electrically connected to the carrier;
a heat spreader, disposed on the carrier, wherein the heat spreader and the carrier together form a closed space, and the chip is located in the closed space; and
a thermal interface material (TIM) located in the closed space, wherein the TIM is in contact with the inner surface of the heat spreader.

9. The chip package as claimed in claim 8, wherein the heat spreader comprises:
a thermal plate; and
a thermal ring, disposed on the thermal plate, wherein the thermal ring and the thermal plate together form a cavity, and the thermal ring is located between the thermal plate and the carrier.

10. The chip package as claimed in claim 9, wherein the thermal plate and the thermal ring are integrally formed.

11. The chip package as claimed in claim 9, wherein the heat spreader further comprises a plurality of fins disposed on one side of the thermal plate opposite to the thermal ring.

12. The chip package as claimed in claim 8, wherein the TIM is solder paste, thermal grease, or epoxy resin with silicon dioxide or silver added.

13. The chip package as claimed in claim 8, further comprising:
a plurality of conductive bumps, disposed between the chip and the carrier; and
an underfill layer, encaplulating the conductive bumps.

14. The chip package as claimed in claim 8, wherein the carrier is a circuit board.

15. A method of manufacturing a chip package, comprising:
providing a carrier;
disposing at least one chip on the carrier;
connecting the chip to the carrier;
disposing a thermal ring on the carrier, such that the thermal ring surrounds the chip, wherein a containing space is defined by the carrier, the thermal ring and the chip;
filling the containing space surrounded by the thermal ring on the carrier with a thermal interface material (TIM), such that the TIM encaplulates the chip; and
disposing a thermal plate on the thermal ring such that the thermal plate covers the chip and a closed space defined by the thermal plate, the thermal ring and the carrier is filled with the TIM.

16. The method of manufacturing a chip package as claimed in claim 15, wherein the steps of disposing the chip on the carrier and connecting the chip to the carrier comprises:
forming a plurality of conductive bumps on the chip;
disposing the chip on the carrier such that the conductive bumps can electrically connect the chip and the carrier; and
forming an underfill layer so as to encapsulate the conductive bumps.

17. The method of manufacturing a chip package as claimed in claim 15, wherein after the step of filling the containing space with the TIM, further comprising a step of removing gases from the interior of the TIM.

18. The method of manufacturing a chip package as claimed in claim 17, wherein the TIM is solid or liquid, and the step of removing the gases from the interior of the TIM comprises vacuum extraction.

19. The method of manufacturing a chip package as claimed in claim 17, wherein the TIM is liquid, and the step of removing the gases from the interior of the TIM comprises heating the TIM.

20. The method of manufacturing a chip package as claimed in claim 17, wherein after the step of removing the gases from the interior of the TIM, the method further comprises a step of putting the TIM in the containing space again to fill the containing space and to encapsulate the chip.
